(19) United States
(12) Patent Application Publication
(10) Pub. No.: US 2023/0045809 A1
(43) Pub. Date: Feb. 16, 2023

(54) METHOD FOR AUTOMATICALLY CLEANING A PROBE CARD AND SYSTEM FOR AUTOMATICALLY PERFORMING A NEEDLE CLEANING

(71) Applicant: NANYA TECHNOLOGY CORPORATION, New Taipei City (TW)

(72) Inventors: Che-Wei CHEN, New Taipei City (TW); Ting-Wei YU, New Taipei City (TW); Chih-Hsiang LIN, New Taipei City (TW)

(21) Appl. No.: 17/444,836

(22) Filed: Aug. 11, 2021

(51) Int. Cl. G01R 3/00; G01R 1/02; B08B 7/00

(52) U.S. Cl. CPC G01R 3/00; B08B 7/0028; G01R 1/025; G01R 1/07342

(57) ABSTRACT

A method for automatically cleaning a probe card includes the following operations. A first wafer is tested in a chamber of a testing machine. A yield of the first wafer is monitored by a tool online monitor system (TOMS). An instruction file is transmitted by the TOMS to a tester, in which the instruction file compiles a first program code of the TOMS into a second program code of the tester. The second program code of the tester is received by the tester. A general purpose interface bus (GPIB) command is transferred to a testing machine by the tester. A cleaning operation is performed by the testing machine.

### BACKGROUND

### FIELD OF INVENTION

The present invention relates to a method for automatically cleaning a probe card and a system for automatically performing a needle cleaning.

### DESCRIPTION OF RELATED ART

Accompanying with the development of semiconductor technologies, the performances of an integrated circuit (IC) has become greater. In general, the IC undergoes several procedures, such as a design procedure, a manufacture procedure, and a packaging procedure, etc. After the manufacture procedure, a probe card is used for testing dies of a wafer to assure the quality of the IC.

However, a testing operation for testing dies of the wafer meets the challenge of long-term testing. For example, undesired debris and particles would generate on needles of the probe card during the testing operation, so that the testing operation would be terminated to avoid affecting the testing results. The testing operation of the wafer would continue after the needles of the probe card are cleaned.

In view of the descriptions above, there is a need for a novel method and a novel system to overcome the problems mentioned above.

### SUMMARY

One aspect of the present disclosure is to provide a method for automatically cleaning a probe card. The method includes the following operations. A first wafer in a chamber of a testing machine is tested. A yield of the first wafer is monitored by a tool online monitor system (TOMS). An instruction file is transmitted by the TOMS to a tester, in which the instruction file compiles a first program code of the TOMS into a second program code of the tester. The second program code of the tester is received by the tester. A general purpose interface bus (GPIB) command is transferred to a testing machine by the tester. A cleaning operation is performed by the testing machine.

According to some embodiments of the present disclosure, the method further includes a second wafer is tested after performing the cleaning operation by the testing machine.

According to some embodiments of the present disclosure, the second program code of the tester is readable by a Linux operating system.

According to some embodiments of the present disclosure, the tester includes a system controller, a local area network (LAN), and a general purpose interface bus (GPIB), and the system controller connects to the LAN and the GPIB.

According to some embodiments of the present disclosure, the second program code of the tester is received through the LAN of the tester.

According to some embodiments of the present disclosure, the second program code of the tester is transferred through the GPIB of the tester.

According to some embodiments of the present disclosure, the method further includes the first wafer is unloaded from the chamber and a polishing plate is loaded into the chamber before performing the cleaning operation.

According to some embodiments of the present disclosure, the cleaning operation includes a needle tip of the probe card is polished.

One aspect of the present disclosure is to provide a system for automatically performing a needle cleaning. The system includes a tool online monitor system (TOMS), a tester, and a testing machine. The tester connects to the TOMS, and the tester includes a system controller. The testing machine connects to the tester, in which the testing machine includes a general purpose interface bus (GPIB) connector. The TOMS transmits an instruction file to the tester, and the instruction file compiles a first program code of the TOMS into a second program code of the tester. The tester receives the second program code of the tester and transfers a GPIB command into the GPIB connector. The testing machine performs a cleaning operation after receiving the GPIB command.

According to some embodiments of the present disclosure, a yield of a wafer is monitored by the TOMS.

According to some embodiments of the present disclosure, the second program code of the tester is readable by a Linux operating system.

According to some embodiments of the present disclosure, the tester includes a local area network (LAN) and a GPIB, and the system controller connects to the LAN and the GPIB.

According to some embodiments of the present disclosure, the second program code of the tester is received through the LAN of the tester.

According to some embodiments of the present disclosure, the second program code of the tester is transferred through the GPIB of the tester.

According to some embodiments of the present disclosure, the GPIB command is received through the GPIB connector.

According to some embodiments of the present disclosure, the testing machine includes a probe card for testing a wafer, and the cleaning operation cleans the probe card.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of an automatically cleaning system for a probe card in accordance with some embodiments of the present disclosure.

FIG. 2 is an enlarged view of a tester in accordance with some embodiments of the present disclosure.

FIG. 3 is an enlarged view of a testing machine with a testing system in accordance with some embodiments of the present disclosure.

FIG. 4 is an enlarged view of a testing machine with a cleaning system in accordance with some embodiments of the present disclosure.

FIG. 5 is a flowchart of a method for automatically cleaning a probe card in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. It should be understood that the number of any elements/components is merely for illustration, and it does not intend to limit the present disclosure.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments.

In a testing operation of a wafer including multiple dies, the dies are tested by a testing system. The testing system could include a probe card, a prober, a tester. The probe card is an interface between an electronic test system and a device under test (DUT), for example, the tester and the die. In addition, different probe cards have different circuit patterns according to DUTs with different integrated circuit (IC) designs. The probe card includes multiple needles and the needles can contact bonding pads of the dies of the wafer. The prober is used for loading and unloading the dies of the wafer through a carrier, so that the bonding pads of the dies of the wafer can align with tips of the needles of the probe card. The tester is used for transmitting electronic signals to the dies.

During the testing operation, undesired debris and particles would generate on the needles of the probe card, and the debris and particles would affect the testing result of a DUT (for example, a wafer). Therefore, it is important to perform a cleaning operation of the probe card. Generally, the undesired debris and particles can be removed by the following two methods. The first method is to set a machine scheduling (such as time schedule) according to a DUT to regularly perform the cleaning operation. However, different DUTs have different machine schedulings. In other words, based on the DUT itself, each DUT has different machine scheduling. Therefore, the first method is not suitable for all DUTs. Furthermore, the second method to remove the undesired debris and particles is a manual cleaning operation. Specifically, a testing machine would temporarily stop to test when an abnormal yield (for example, low yield) is monitored, and then operating personnel would come to perform the cleaning operation. After the cleaning operation is performed, the testing machine would rework for the testing operation. The gap time from the moment at the testing machine stop to the moment the testing machine restart would decrease the test rate of the testing operation.

However, the first method mentioned above has the problem that it is not suitable for all DUTs, and the second method mentioned above has the problem of the decrease of the test rate because of the gap time. Therefore, there is a need to a novel method and a novel system to overcome the problems mentioned above. The present disclosure provides a method of automatically cleaning the probe card and a system for automatically performing the needle cleaning, in which it can automatically perform the cleaning operation of the probe card. The present disclosure is suitable for all DUTs, and the present disclosure has the advantages of increasing the test rate, reducing manufacturing cost, avoiding a yield loss, and avoiding a rework rate. Embodiments of the method and the system of the present disclosure will be described in detail below.

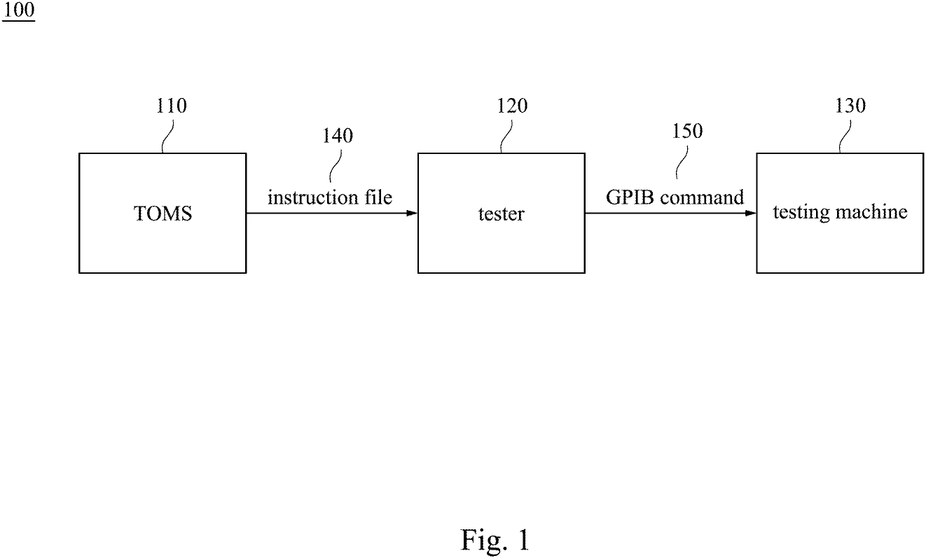

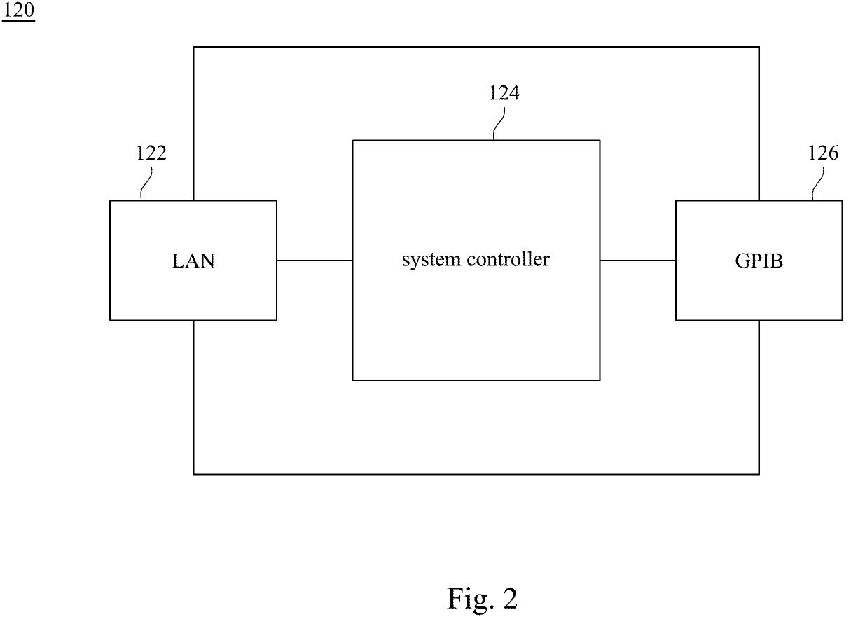

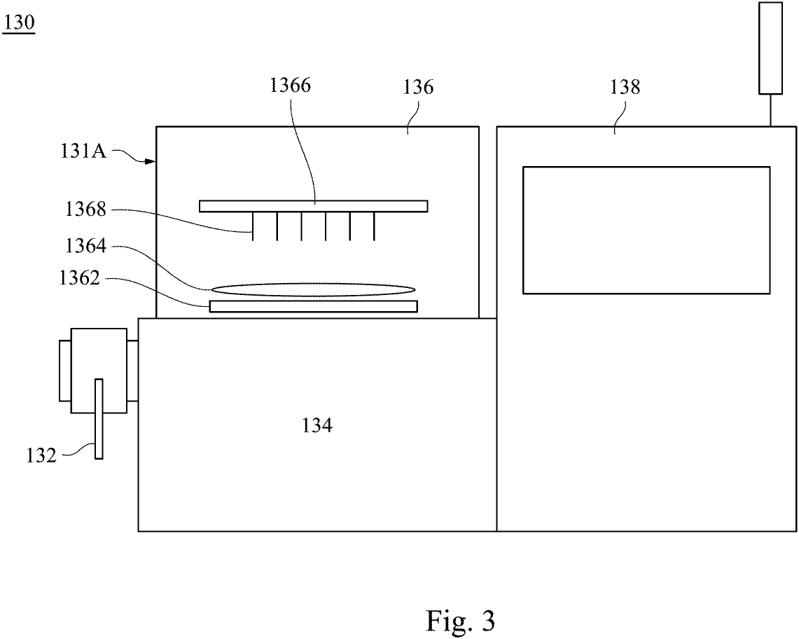

FIG. 1 is a block diagram of an automatically cleaning system 100 for a probe card in accordance with some embodiments of the present disclosure. The automatically cleaning system 100 includes a Tool Online Monitor System (TOMS) 110, a tester 120, and a testing machine 130. The TOMS 110, the tester 120, and the testing machine 130 are electrically connected to each other. In some embodiments, the TOMS 110 can monitor a real-time yield of a wafer and/or a progress of the wafer. In some embodiments, the TOMS 110 can monitor abnormal condition, for example, an abnormal yield. In some embodiments, the TOMS 110 is connected to a display, such as a computer screen, to show the progress of the wafer and/or a diagram of the wafer. The tester 120 and the testing machine 130 will be described in detail below with FIG. 2 and FIG. 3.

FIG. 2 is an enlarged view of the tester 120 in accordance with some embodiments of the present disclosure. The tester 120 is configured to transmit electronic signals, such as a program code. In some embodiments, the tester 120 includes a local area network (LAN) 122, a system controller 124, and a general purpose interface bus (GPIB) 126. The system controller 124 connects to the LAN 122 and the GPIB 126. With the system controller 124, the LAN 122 can receive a program code, and the GPIB 126 can transfer the program code. In some embodiments, the system controller 124 is a Linux operating system. In some embodiments, manufacturer of the tester 120 is Advantest Corporation.

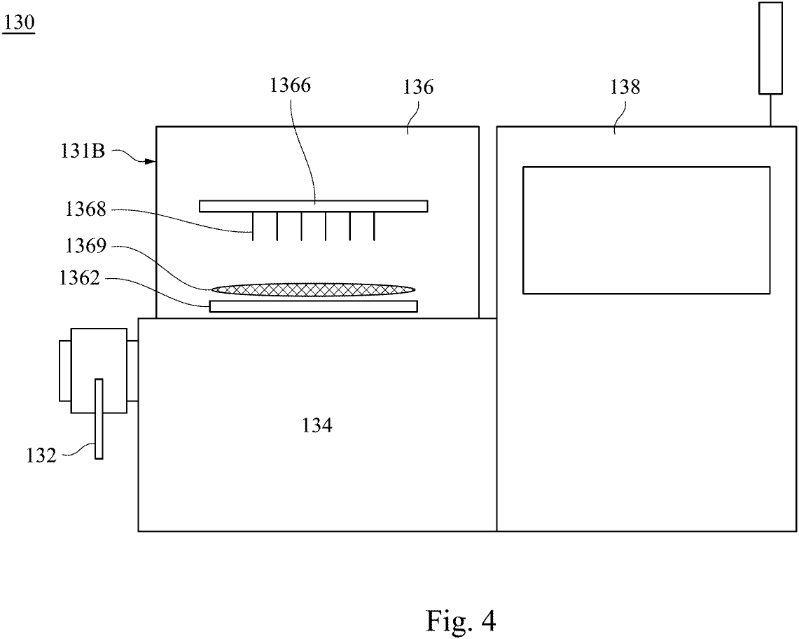

FIG. 3 is an enlarged view of a testing machine 130 with a testing system 131A in accordance with some embodiments of the present disclosure. The testing machine 130 includes the testing system 131A where a wafer 1364 is tested. After the testing system 131A performs the testing operation of the wafer 1364, a yield of the wafer 1364 will be known. It is understood that, the testing machine 130 is configured to test the wafer 1364 which undergoes manufacture procedure. Specifically, before the wafer 1364 is under tested, the wafer 1364 has been manufactured in another machine (or other machines) rather than in the testing machine 130. In some embodiments, the testing machine 130 includes a cabin 132, a general purpose interface bus (GPIB) connector 134, a first chamber 136, and a second chamber 138. The cabin 132 is configured to receive and/or transfer electronic signals, and connects to the GPIB connector 134. In the first chamber 136, it includes a prober 1362, the wafer 1364, and a probe card 1366. In some embodiments, the prober 1362 is configured to control the wafer 1364, for example, prober 1362 can load, unload, align, move, heat and/or cool the wafer 1364. In some embodiments, the prober 1362 can be used for a cleaning operation of the probe card 1366. The probe card 1366 includes multiple needles 1368 and the needles 1368 can contact bonding pads (not shown) of the dies (not shown) of the wafer 1364. The needles include conductive material. In some embodiments, the probe card 1366 tests the wafer 1364 in cooperation with the prober 1362. The second chamber 138 includes a loading unit (not shown) and an unloading unit (not shown), in which the wafer 1364, the probe card 1366, and/or a polishing plate (shown in FIG. 4) can be loaded and/or unloaded through the loading unit and the unloading unit. In the embodiment of FIG. 3, the first chamber 136 is a space where the wafer 1364 is under the testing operation.

FIG. 4 is an enlarged view of the testing machine 130 with a cleaning system 131B in accordance with some embodiments of the present disclosure. In the embodiments of FIG. 4, the first chamber 136 is a space where the probe card 1366 is under the cleaning operation. It is noticed that the testing machine 130 with the cleaning system 131B is similar to the testing machine 130 with the testing system 131A (shown in FIG. 3), with similar features being labeled by similar numerical references, and descriptions of the similar features are not repeated herein. Specifically, the wafer 1364 in FIG. 3 is replaced by a polishing plate 1369 in FIG. 4. More specifically, the wafer 1364 in FIG. 3 is unloaded through the unloading unit of the second chamber 138, and then the polishing plate 1369 is loaded through the loading unit of the second chamber 138, as shown in FIG. 4. The prober 1362 is also used to assist the unloading operation of the wafer 1364 and the loading operation of polishing plate 1369. The cleaning system 131B includes the prober 1362, the probe card 1366 having multiple needles 1368, and the polishing plate 1369. The testing machine 130 in FIG. 4 is the embodiment when performing a cleaning operation of the prober card 1366. In some embodiments, the cleaning operation includes polishing needle tips of needles 1368 of the probe card 1366. For example, the needle tips of needles 1368 are polished by spinning the polishing plate 1369, and then the polishing plate 1369 is unloaded through the unloading unit of the second chamber 138. In other embodiments, the cleaning operation includes adhering to undesired debris and particles. For example, undesired debris and particles are adhered to by contacting an adhesion plate, and then the adhesion plate is unloaded through the unloading unit of the second chamber 138. In some embodiments, as shown in FIG. 4, the cleaning operation of the prober card 1366 can be performed in the first chamber 136 where is the same as the wafer 1364 is tested. In some embodiments, the material of the polishing plate 1369 includes SiC.

Please refer to FIG. 1 again. The automatically cleaning system 100 further includes an instruction file 140 and a general purpose interface bus (GPIB) command 150. The instruction file 140 can compile a program code into another program code. For example, the instruction file 140 compiles a program code of the TOMS 110 into a program code of the tester 120. The GPIB command 150 is a command signal that can drive the testing machine 130 to perform the cleaning operation as mentioned above.

It is understood that additional operations can be provided before, during, and after processes shown by FIG. 1 to FIG. 4, and some of the operations described below can be replaced or eliminated, for additional embodiments of the process. The order of the operations/processes may be interchangeable.

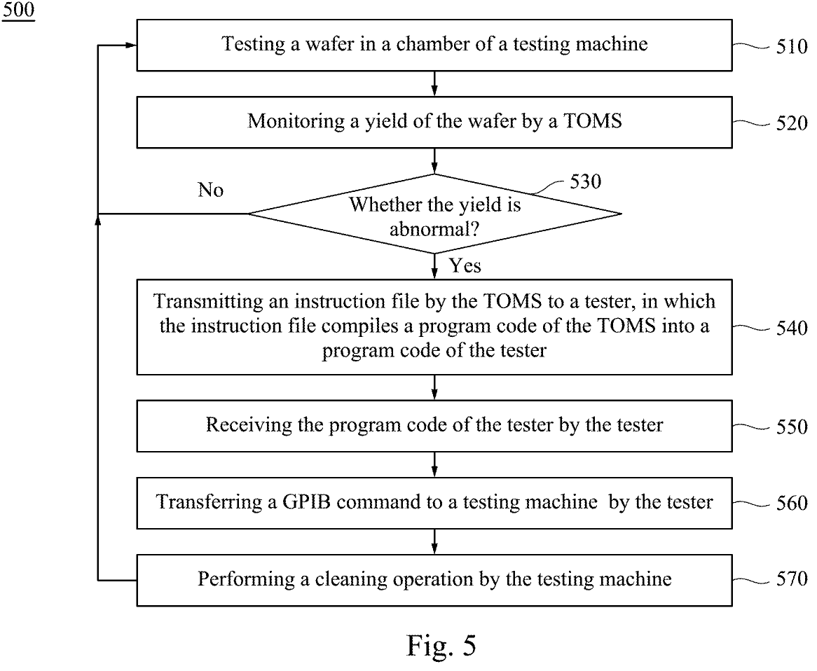

FIG. 5 is a flowchart of a method 500 for automatically cleaning the probe card 1366 in accordance with some embodiments of the present disclosure. In operation 510, the wafer 1364 in the first chamber 136 of the testing machine 130 is tested. It should be noticed that the wafer herein is not limited to the wafer 1364, and it can also refer to another wafer which is needed to be tested. The method 500 continues with operation 520, a yield of the wafer 1364 is monitored by the TOMS 110. Specifically, the TOMS 110 monitors a real-time yield of the wafer 1364. In operation 530, it is needed to determine whether the yield is abnormal. Specifically, the TOMS 110 would automatically determine whether the yield of the wafer 1364 is abnormal. If the yield of the wafer 1364 is normal, the method 500 returns to the operation 510, in which the testing machine 130 would continue to test the wafer 1364. However, if the yield of the wafer 1364 is abnormal, the method 500 continues with operation 540, in which the TOMS 110 would transmit the instruction file 140 to the tester 120. In the operation 540, the instruction file 140 compiles a program code of the TOMS 110 into a program code of the tester 120.

The method 500 continues with operation 550, the program code of the tester 120 is received by the tester 120. In operation 560, the GPIB command 150 is transferred to the testing machine 130 by the tester 120. In operation 570, a cleaning operation is performed by the testing machine 130 (for example, testing system 131A). In some embodiments, the GPIB connector 134 in the testing machine 130 receives the GPIB command 150, so that the testing machine 130 performs the cleaning operation. After the cleaning operation, the method 500 returns to the operation 510. Specifically, in the cleaning operation of the prober card 1366, undesired debris and particles on needle tips of the probe card 1366 are removed. More specifically, the wafer 1364 is unloaded from the first chamber 136 and the polishing plate 1369 is loaded into the first chamber 136 before performing the cleaning operation. It is understood that the polishing plate 1369 can be replaced by an adhesion plate depending on the extent of the debris and particles. In some embodiments, the material of the adhesion plate includes polymer. The embodiments of the cleaning operation are not repeated herein. In some embodiments, the wafer 1364 is reloaded into the first chamber 136 for testing operation after performing the cleaning operation. In other embodiments, another wafer is loaded into the first chamber 136 for testing operation after performing the cleaning operation.

In detail, once the TOMS 110 automatically monitors an abnormal yield (for example, low yield) of the wafer 1364, the TOMS 110 will automatically transmit the instruction file 140 to the tester 120, and then the instruction file 140 automatically compiles a program code of the TOMS 110 into a program code of the tester 120. Next, the tester 120 automatically receives the complied program code, and then automatically transmits the GPIB command 150 to the testing machine 130. After the testing machine 130 automatically received the GPIB command 150, the testing machine 130 automatically performs the cleaning operation of the probe card 1366. Finally, the multiple needles 1368 are automatically cleaned. The operations mentioned above are all automatically performed, so that the cleaning operation of the probe card 1366 can be immediately performed without waiting for operating personnel for manual cleaning operation. Therefore, the testing machine 130 can continue to test the wafer 1364 (or another wafer) after the automatically cleaning operation, thereby increasing test rate of the testing machine 130. Furthermore, the testing machine 130 is not limited only one kind of wafer and can be used for all kinds of DUTs.

The present disclosure provides the method of automatically cleaning the probe card and the system for automatically performing the needle cleaning, in which it can automatically perform the cleaning operation of the probe card. The present disclosure is suitable for all DUTs and has the advantages of increasing the test rate, reducing manufacturing cost, avoiding a yield loss, and avoiding a rework rate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for automatically cleaning a probe card, comprising:
testing a first wafer in a chamber of a testing machine;
monitoring a yield of the first wafer by a tool online monitor system (TOMS);
transmitting an instruction file by the TOMS to a tester, wherein the instruction file compiles a first program code of the TOMS into a second program code of the tester;
receiving the second program code of the tester by the tester;
transferring a general purpose interface bus (GPIB) command to a testing machine by the tester; and
performing a cleaning operation by the testing machine.

2. The method of claim 1, further comprising testing a second wafer after performing the cleaning operation by the testing machine.

3. The method of claim 1, wherein the second program code of the tester is readable by a Linux operating system.

4. The method of claim 1, wherein the tester comprises a system controller, a local area network (LAN), and a general purpose interface bus (GPIB), and the system controller connects to the LAN and the GPIB.

5. The method of claim 4, wherein the second program code of the tester is received through the LAN of the tester.

6. The method of claim 4, wherein the second program code of the tester is transferred through the GPIB of the tester.

7. The method of claim 1, further comprising unloading the first wafer from the chamber and loading a polishing plate into the chamber before performing the cleaning operation.

8. The method of claim 1, wherein the cleaning operation comprises polishing a needle tip of the probe card.

9. A system for automatically performing a needle cleaning, comprising:
a tool online monitor system (TOMS);
a tester connecting to the TOMS, and the tester comprises a system controller; and
a testing machine connecting to the tester, wherein the testing machine comprises a general purpose interface bus (GPIB) connector;
wherein the TOMS transmits an instruction file to the tester, and the instruction file compiles a first program code of the TOMS into a second program code of the tester;
wherein the tester receives the second program code of the tester and transfers a GPIB command into the GPIB connector; and
wherein the testing machine performs a cleaning operation after receiving the GPIB command.

10. The system of claim 9, wherein a yield of a wafer is monitored by the TOMS.

11. The system of claim 9, wherein the second program code of the tester is readable by a Linux operating system.

12. The system of claim 9, wherein the tester comprises a local area network (LAN) and a GPIB, and the system controller connects to the LAN and the GPIB.

13. The system of claim 12, wherein the second program code of the tester is received through the LAN of the tester.

14. The system of claim 12, wherein the second program code of the tester is transferred through the GPIB of the tester.

15. The system of claim 9, wherein the GPIB command is received through the GPIB connector.

16. The system of claim 9, wherein the testing machine comprises a probe card for testing a wafer, and the cleaning operation cleans the probe card.
